(19) United States
(12) Patent Application Publication
(10) Pub. No.: US 2025/0159906 A1
(43) Pub. Date: May 15, 2025

(54) ELECTRONIC DEVICE

(71) Applicant: STMicroelectronics International N.V., Geneva (CH)

(72) Inventors: Alain OSTROVSKY, Grenoble (FR); Jerome DUBOIS, Grenoble (FR); Latifa DESVOIVRES, Grenoble (FR); Simon JEANNOT, Grenoble (FR); Christian BOCCACCIO, Bernin (FR)

(73) Assignee: STMicroelectronics International N.V., Geneva (CH)

(21) Appl. No.: 18/935,091

(22) Filed: Nov. 1, 2024

(30) Foreign Application Priority Data
Nov. 9, 2023 (FR) 2312256

(51) Int. Cl. H10B 63/00; H10B 63/10; H10N 70/00; H10N 70/20

(52) U.S. Cl. CPC H10B 63/80; H10B 63/10; H10N 70/063; H10N 70/231; H10N 70/8413

(57) ABSTRACT

A method manufactures a memory including at least one first phase-change memory cell, each first cell including a resistive element, a first metal layer, and a second layer made of a phase-change material, the first layer being located between the resistive element and the second layer. The method includes the forming of a level including the resistive element, the forming of a third metal layer on the level, the etching of the third layer, and then the forming of the second layer.

### CROSS-REFERENCE TO RELATED APPLICATION(S)

This application claims the priority benefit of French patent application number FR2312256, filed on Nov. 9, 2023, entitled “Dispositif électronique,” which is hereby incorporated by reference to the maximum extent allowable by law.

### BACKGROUND

### Technical Field

The present disclosure generally concerns electronic devices and more precisely electronic devices including phase-change memories and their manufacturing methods.

### Description of the Related Art

A phase-change material is a material having the ability to change crystalline state under the effect of heat, and more specifically to switch between a crystalline state and an amorphous state, more highly resistive than the crystalline state. This phenomenon is used to define two memory states, for example 0 and 1, differentiated by the resistance measured through the phase-change material.

It would be beneficial to improve electronic chips including a memory circuit including memory cells based on a phase-change material, and their manufacturing processes.

### BRIEF SUMMARY

An embodiment provides a method of manufacturing a memory including at least one first phase-change memory cell, each first cell including a resistive element, a first metal layer, and a second layer made of a phase-change material, the first layer being located between the resistive element and the second layer, the method including: a. the forming of a level including the resistive element; b. the forming of a third metal layer on the level; c. the etching of the third layer; and then d. the forming of the second layer.

According to an embodiment, the first metal layer is made of TiSiN, of TiN, or of TaN, the third metal layer being made of the same material as the first layer.

According to an embodiment, the device includes at least two first cells, the first metal layers of different first cells being separated from one another.

According to an embodiment, the first metal layer is in contact with the resistive element and with the second layer made of a phase-change material.

According to an embodiment, the device includes at least one second phase-change memory cell including a resistive element and a second layer made of a phase-change material, the second layer is in contact with the resistive element, the method including the etching of the first layer at the locations of the second cells.

According to an embodiment, the device includes rows of memory cells, the cells of a same row include a second common layer made of a phase-change material.

According to an embodiment, the memory cells each include a portion of the second layer made of a phase-change material, the portions of the second layer made of a phase-change material of the individual cells being separated from one another.

According to an embodiment, the method includes a step e., subsequent to step d., in which the portions of the first level and of the second layer made of a phase-change material located around the memory cells are etched.

According to an embodiment, the device includes at least two rows of memory cells, the method including a step e., subsequent to step d., in which the portions of the first level and of the second layer made of a phase-change material located between the two rows of memory cells are etched.

According to an embodiment, the device includes at least two columns of memory cells, the method including a step f. subsequent to step e., in which the portions of the first level and the second layer made of a phase-change material located between the two columns of memory cells are etched.

According to an embodiment, step c. includes the etching of the third metal layer so as to form the first metal layer.

According to an embodiment, step c. includes the etching of the third metal layer so as to form strips, each including the first layers of first cells of a same column of memory cells.

According to an embodiment, step e. includes the etching of the strips to form the first metal layers.

According to an embodiment, the level includes a fourth insulating layer in which the resistive element is arranged, the first layer being in contact with the resistive element and the fourth layer, the second layer being formed on and in contact with the first layer and the level.

According to an embodiment, a method includes forming a first level including a resistive element of a first phase-change memory cell and forming a metal layer on the first level. The method includes forming, from the metal layer, a conductive element of the first phase-change memory cell on the resistive element by etching the metal layer and forming a layer of phase-change material on the first level and covering a sidewall and a top surface of the conductive element.

According to an embodiment, a method includes forming a plurality of resistive elements in a first insulating layer and each having a top surface substantially coplanar with a top surface of the first insulating layer. The method includes forming a plurality of conductive elements each in contact with the top surface of a respective resistive element and the top surface of the insulating layer. The method includes forming a layer of phase change material on the top surface of the insulating layer, on a sidewall of each conductive element, and on the top surface of each conductive element. Each of a plurality of first phase-change memory cells includes a respective resistive element, a respective conductive element, and a respective portion of the layer of phase-change material.

According to an embodiment, a device includes a layer of insulating material and a phase-change memory cell. The phase-change memory cell includes a metal contact and a resistive element in the layer of insulating material and on a top surface of the metal contact. The phase-change memory cell includes a conductive element in contact with a top surface of the resistive element and the layer of insulating material and a layer of phase-change material on a top surface of the layer of insulating material, on a side surface of the conductive element, and on a top surface of the conductive element.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 shows an embodiment of an electronic device;

FIG. 2 illustrates the operation of the device of FIG. 1;

FIG. 3 shows a device resulting from a step of a method of manufacturing the device of FIG. 1;

FIG. 4 shows a device resulting from a step of a method of manufacturing the device of FIG. 1;

FIG. 5 shows a device resulting from a step of a method of manufacturing the device of FIG. 1;

FIG. 6 shows a device resulting from a step of a method of manufacturing the device of FIG. 1;

FIG. 7 shows a device resulting from a step of a method of manufacturing the device of FIG. 1;

FIG. 8 illustrates several possible cases of alignment;

FIG. 9 shows a device resulting from a step of a method of manufacturing the device of FIG. 1;

FIG. 10 shows a device resulting from a step of another method of manufacturing another device of FIG. 1;

FIG. 11 shows a device resulting from a step of another method of manufacturing the device of FIG. 1; and

FIG. 12 shows another embodiment of an electronic device.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10%, preferably of plus or minus 5%.

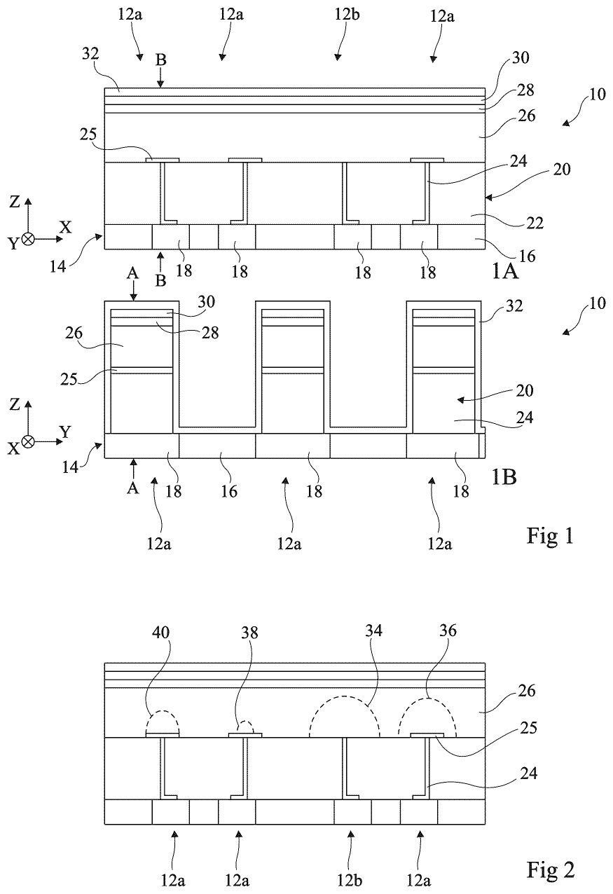

FIG. 1 shows an embodiment of an electronic device 10. More specifically, FIG. 1 shows two cross-section views 1A and 1B. View 1A corresponds to a cross-section view along plane A-A of view 1B, and view 1B corresponds to a cross-section view along plane B-B of view 1A. Planes A-A and B-B are preferably substantially perpendicular.

Device 10 includes a memory region. Said memory region includes at least one memory cell 12a, 12b, preferably a plurality of memory cells 12a, 12b. Memory cells 12a, 12b are phase-change memory cells. Device 10 includes a first type of memory cell 12a. Device 10 includes at least one cell 12a. FIG. 1 shows three 12a cells in view 1A and three 12a cells in view 1B. Device 10 includes, for example, a second type of memory cell 12b. FIG. 1 includes one cell 12b, in view 1A.

Memory cells 12a, 12b are arranged in a memory array. View 1A shows memory cells of a same row of the memory array. Similarly, view 1B shows memory cells of the same column of the memory array. The row of cells 12a, 12b in view 1A thus extends in a first X direction. The column of cells 12a, 12b in view 1B thus extends in a second Y direction, for example substantially orthogonal to the X direction. The memory array is a “wall” type structure, that is, cells of same rows are located in a same wall.

Device 10 includes a level 14. Level 14 includes an insulating layer 16. Insulating layer 16 is made, for example, of silicon oxide or of silicon nitride. Level 14 further includes conductive contacts 18, for example made of metal, for example, of tungsten. The conductive contacts for example extend along the entire height of layer 16. One end of each conductive contact 18 is flush with an upper surface of layer 16. Device 10 includes at least as many contacts 18 as there are memory cells 12. Each memory cell 12a, 12b is located on a contact 18.

Each row of memory cells includes a level 20. The levels 20 of the different rows are separated from one another. The levels 20 of the different rows are thus not in contact.

Each level 20 includes an insulating layer 22, for example made of silicon oxide. Each insulating layer 22 extends over the upper surface of layer 16 and over the upper ends of contacts 18, in particular of contacts 18 corresponding to the memory cells in the row.

Each level 20 further includes conductive elements 24. Each level 20 preferably includes as many elements 24 as there are cells 12. Each cell 12a, 12b includes one element 24. Elements 24 correspond to resistive elements. Elements 24 correspond to heating elements. Elements 24 are, for example, L-shaped in the plane of view 1A. Elements 24 include a vertical portion extending from the end of contact 18 corresponding to the memory cell of element 24 to the upper surface of layer 22. Thus, the upper end of the vertical portion is flush with the upper surface of layer 22 and the lower end of the vertical portion is in contact with contact 18. Element 24 for example includes a horizontal portion in contact with the lower end of the horizontal portion and extending at least partially, preferably entirely, over the upper end of contact 18.

Each cell 12a includes a layer 25. Each layer 25 is located on the upper surface of level 20. More precisely, the layer 25 of each cell 12a is located so as to be in contact with the upper end of the element 24 of the corresponding memory cell and with layer 22. Each layer 25 is in contact with only one element 24, that is, the element 24 of the memory cell including layer 25. Layers 25 are separated from one another. The layer 25 of each cell 12a corresponds to a metal element, a metal structure, a conductive structure, or a second resistive element of the cell 12a.

Layer 25 preferably has a dimension in the Y direction substantially equal to the dimension of the upper surface of layer 22. Layer 25 is made of a conductive material, preferably a highly-resistive metal, for example made of TiSiN, of TiN, or of TaN.

Each row of memory cells further includes a layer 26 made of a phase-change material. Layer 26 is for example made of an alloy of germanium, of antimony, and of tellurium. Layer 26 is for example made of an alloy of germanium, of antimony, of tellurium, and of selenium. Layer 26 may for example include dopants such as arsenic, indium, carbon, or nitrogen. Each layer 26 extends in the row direction of the corresponding memory array. Each layer 26 extends over the layers 25 and the level 20 of the corresponding row. Thus, each layer 26 covers, and preferably is in contact with, layers 25 and level 20. More precisely, each layer 26 covers, for example entirely, and preferably is in contact with, the layers 25 of the memory cells 12a of the corresponding row and the ends of the elements 24 of the memory cells 12b of the corresponding row. Each layer 26 covers, preferably entirely, the upper surface of layer 22.

The layers 25 of a same row of cells are separated from one another by portions of layer 26.

Each row of memory cells further includes a conductive layer 28. Layer 28 is preferably made of a metal. Layer 28 corresponds to an electrode of the memory cell. Layer 28 extends over the upper surface of layer 26. Layer 28 covers, preferably entirely, the upper surface of layer 26. Layer 28 is preferably in contact with layer 26, preferably at all points.

Each row of memory cells further includes an insulating layer 30. Layer 30 corresponds to a passivation layer. Layer 30 extends over the upper surface of layer 28. Layer 30 covers, preferably entirely, the upper surface of layer 28. Layer 30 is preferably in contact with layer 28, preferably at all points.

Device 10 further includes a layer 32. Layer 30 is made of an insulating material, for example, of silicon nitride. Layer 32 conformally covers the above-described structure. In other words, layer 32 covers the stacks of layers of the rows of the array. In other words, each stack, including a level 20, layers 25, and layers 26, 28, 30, is conformally covered by layer 32. Layer 32 thus covers the upper surface of layer 30 and the lateral surfaces of layers 22, 26, 28, 30 and of elements 24. Layer 32 may also cover the lateral surfaces of at least certain layers 25. Layer 32 also covers the portions of the upper surface of level 14 located between the stacks.

FIG. 2 illustrates the operation of the device of FIG. 1. More precisely, FIG. 2 is a cross-section view in the plane of view 1A, illustrating four memory cells, one cell 12b and three cells 12a, in different programming states.

Cells 12b are binary memory cells. In other words, cells 12b can be programmed to contain one among first and second values. In other words, the portion of layer 26 corresponding to each cell 12b may be in a highly-resistive state, the amorphous state, and in a more lightly resistive state, the crystalline state, illustrated in FIG. 2 by the forming of a crystalline area 34 delimited by dotted lines. The programming of each cell 12b thus corresponds to the passing from one of the two states to the other, or conversely. It is not possible to program a third value, different from the first and second values.

Cells 12a are cells which can be programmed to contain one of at least three values. Thus, according to the current flowing through each cell, that is, according to the temperature applied to layer 26, the resulting crystalline region may have different sizes, corresponding to different resistivities. Thus, in the example of FIG. 2, cells 12a may correspond to four different values, three of which correspond to the forming of a crystalline region, the three crystalline regions being delimited by dotted lines. FIG. 2 illustrates regions 34, 36, 38, and 40 of the layer 26 of phase-change material having differing resistances based on the particular programming of the cells. According to an embodiment, the size of the region corresponds to the resistance of a programmed state.

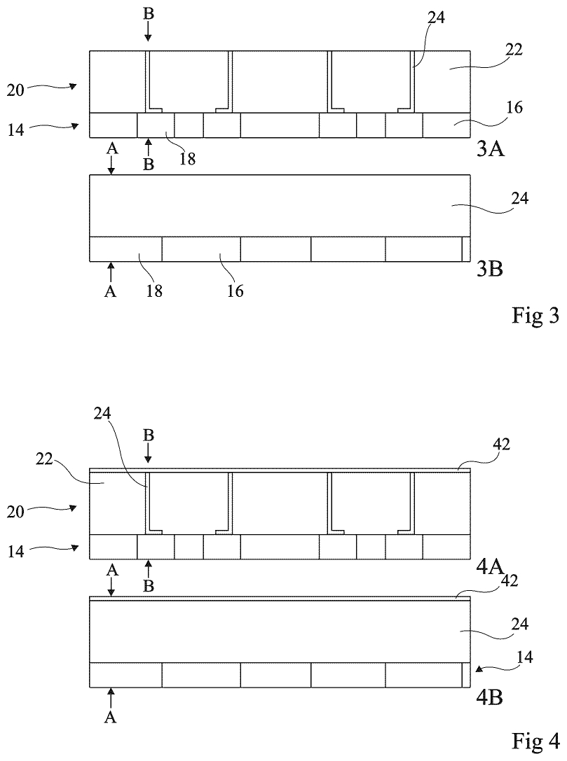

FIGS. 3 to 7 and 9 illustrate steps, preferably successive, of a method of manufacturing the device of FIG. 1.

FIG. 3 shows a device resulting from a step of a method of manufacturing the device of FIG. 1. More precisely, FIG. 3 shows two cross-section views 3A and 3B. View 3A corresponds to a cross-section view along plane A-A of view 3B, and view 3B corresponds to a cross-section view along plane B-B of view 3A. Planes A-A and B-B are preferably substantially perpendicular.

During this step, level 14 is formed. In other words, layer 16 is formed, for example on an upper surface of a substrate, not shown. Contacts 18 are then formed in layer 16. For example, contacts 18 cross layer 16 so as to be flush with the upper surface of layer 16 and to reach the substrate, not shown.

The step of FIG. 3 further includes the forming of level 20. The forming of level 20 for example includes the forming of an insulating layer having a thickness substantially equal to the thickness of layer 22 and, for example, made of the material of layer 22, the forming of a cavity having a side wall extending over the contacts 18 of a column of the memory array and an opposite side wall extending over the contacts 18 of another column of the memory array. A conductive layer made of the material of element 24 is conformally formed on the structure. Spacers made of an insulating material, for example the same material as layer 22, are formed on the walls of the layer so as to cover the locations of elements 24. Portions of the conductive layer not protected by the spacers are then removed, forming elements 24. The cavity is then filled, for example with the material of layer 22, so as to form layer 22.

FIG. 4 shows a device resulting from a step of a method of manufacturing the device of FIG. 1. More precisely, FIG. 4 shows two cross-section views 4A and 4B. View 4A corresponds to a cross-section view along plane A-A of view 4B, and view 4B corresponds to a cross-section view along plane B-B of view 4A. Planes A-A and B-B are preferably substantially perpendicular.

During this step, a layer 42 is formed on the structure. More specifically, layer 42 is formed on level 20. Thus, layer 42 covers, preferably entirely, the upper surface of layer 22 and the upper ends of elements 24. Layer 42 covers at least the upper ends of the elements 24 corresponding to cells 12a.

Layer 42 is made of the material of layers 25. The thickness of layer 42 is substantially equal to the thickness of layers 25.

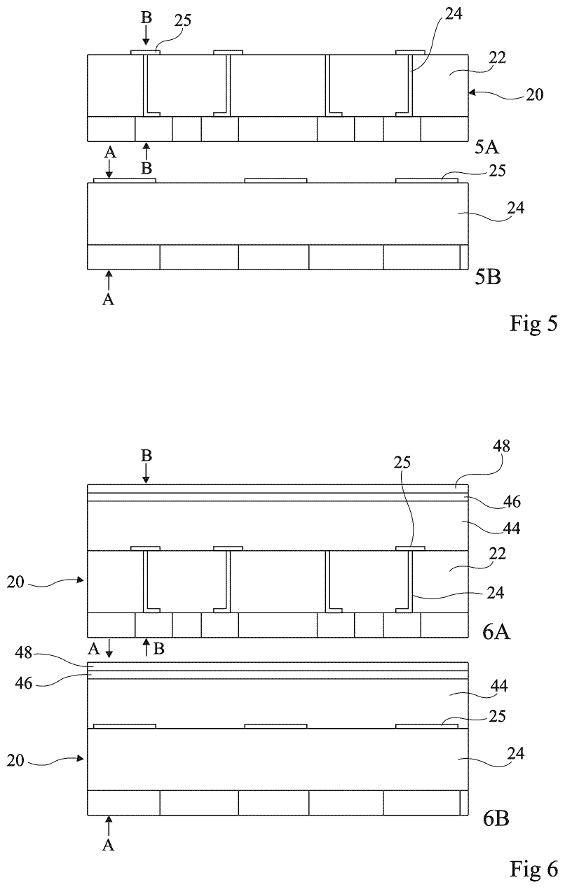

FIG. 5 shows a device resulting from a step of a method of manufacturing the device of FIG. 1. More precisely, FIG. 5 shows two cross-section views 5A and 5B. View 5A corresponds to a cross-section view along plane A-A of view 5B, and view 5B corresponds to a cross-section view along plane B-B of view 5A. Planes A-A and B-B are preferably substantially perpendicular.

The step of FIG. 5 include the etching of layer 42 to form layers 25. The forming of layers 25 preferably includes the etching of layer 42 only. The etching of layer 42 is carried out before the forming of layer 26 of phase-change material.

The etching of layer 42 for example includes the forming of etch masks, not shown, at the locations of layers 25, so as to protect the portions of layer 42 forming layers 25, and the etching of layer 42 around the etch masks.

Alternatively, the etching of layer 42 may include the forming of first etch masks extending in the row direction of the memory array and each covering the portions of layer 42 corresponding to the layers 25 of the row. The etching step then includes the etching of layer 42 around the first masks. The step further includes the forming of second etch masks extending in the column direction of the memory array and each covering the portions of layer 42 corresponding to the layers 25 of the column. The etching step then includes etching layer 42 around the second masks.

FIG. 6 shows a device resulting from a step of a method of manufacturing the device of FIG. 1. More precisely, FIG. 6 shows two cross-section views 6A and 6B. View 6A corresponds to a cross-section view along plane A-A of view 6B, and view 6B corresponds to a cross-section view along plane B-B of view 6A. Planes A-A and B-B are preferably substantially perpendicular.

During this stage, layers 44, 46, 48 are formed on the structure.

Layer 44 is made of the material of layers 26. The thickness of layer 44 is preferably substantially equal to the thickness of layers 26. Layer 44 preferably covers the entire structure. More precisely, layer 44 preferably covers the entire level 20 and layers 25. Thus, all layers 25 and the upper ends of the elements 24 of cells 12b are covered, and preferably in contact, with layer 44. Layer 44 is common to all rows.

Layer 46 is made of the material of layer 28. The thickness of layer 46 is preferably substantially equal to the thickness of layers 28. Layer 46 covers, preferably entirely, layer 44. Layer 46 is preferably in contact with layer 44.

Layer 48 is made of the material of layers 30. The thickness of layer 48 is preferably substantially equal to the thickness of layers 30. Layer 48 covers, preferably entirely, layer 46. Layer 48 is preferably in contact with layer 46.

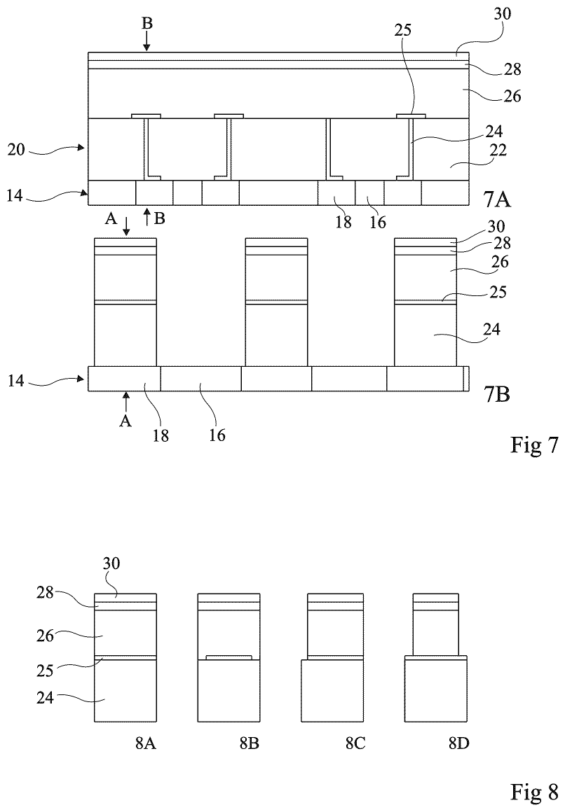

FIG. 7 shows a device resulting from a step of a method of manufacturing the device of FIG. 1. More specifically, FIG. 7 shows two cross-section views 7A and 7B. View 7A corresponds to a cross-section view along plane A-A of view 7B, and view 7B corresponds to a cross-section view along plane B-B of view 7A. Planes A-A and B-B are preferably substantially perpendicular.

The step of FIG. 7 includes the forming of the rows of memory cells. More specifically, FIG. 7 includes the etching of level 20 and of layers 44, 46, 48 between the rows of memory cell so as to form the levels 20 and the layers 26, 28, 30 of the rows of memory cells.

The forming of the rows for example includes the forming of etch masks, each etch mask being located in front of the portions of level 20 and of layers 44, 46, 48 corresponding to a row of the memory array. An etching step, or a plurality of successive etching steps, is then carried out to form the rows. The etching is preferably configured to reach the upper surface of layer 14. The etching step of FIG. 7 preferably does not include the etching, even partial, of layers 25.

It could have been chosen not to etch the layer 42 of FIG. 4 before the forming of layer 26. Layer 42 would then be etched during the step of FIG. 7. However, the method of etching the material of the layer also allows the etching of the material of layer 26, the speed of etching of layer 26 being much higher than the speed of etching of layer 42. Before level 20 can be etched, the etching of layer 42 should be performed. However, during the etching of layer 42, the etching method would cause the lateral etching of layer 26, which would decrease the efficiency of the memory cells and would increase the variability between cells.

FIG. 8 illustrates several possible cases of alignment. FIG. 8 includes four views, each showing a row of a memory array in plane B-B of FIGS. 3 to 7 at the manufacturing step of FIG. 7. The different views represent different possible arrangements of layers 25 in the row of memory cells.

View 8A corresponds to a case in which the etch mask of the step of FIG. 7 is located in front of layer 25. The mask is aligned with layer 25. Thus, during the etching of the row of the memory array, layer 26 is etched to expose the side walls of layer 25. The dimension of the row in the Y direction is then substantially equal to, for example, the dimension of layer 25.

View 8B corresponds to a case in which the dimension of the etch mask in the Y direction is greater than the dimension of layer 25 in the Y direction, and in which the mask faces the entire layer 25 and of the portions of layer 22 and of element 24 surrounding layer 25. Thus, the side walls and the upper surface of layer 25 are covered by layer 26.

In the case of views 8A and 8B, the etching of the rows does not reach layer 25. Thus, although the etching process of layers 26 and 22 etches the material of layer 25 slower, the presence of layers 25 has no impact on the row etching.

View 8C shows a case in which the etch mask is offset with respect to layer 25. Thus, the mask is not located in front of a portion of layer 25.

View 8D corresponds to a case in which the dimension of the etch mask in the Y direction is smaller than the dimension of layer 25 in the Y direction, and in which the mask is located in front of a central portion of layer 25.

In the case of views 8C and 8D, the etching of the row, and more precisely of layer 26, results in the exposing of layer 25. However, the etching of level 20 may be carried out around layer 25. Thus, the etching step is not maintained to etch layer 25, which avoids the unintentional etching of layer 26 and the forming of lateral cavities in layer 26.

Thus, although there is no self-alignment between the etching of the row and the etching of layer 25, this does not impact the advantages of the described embodiment.

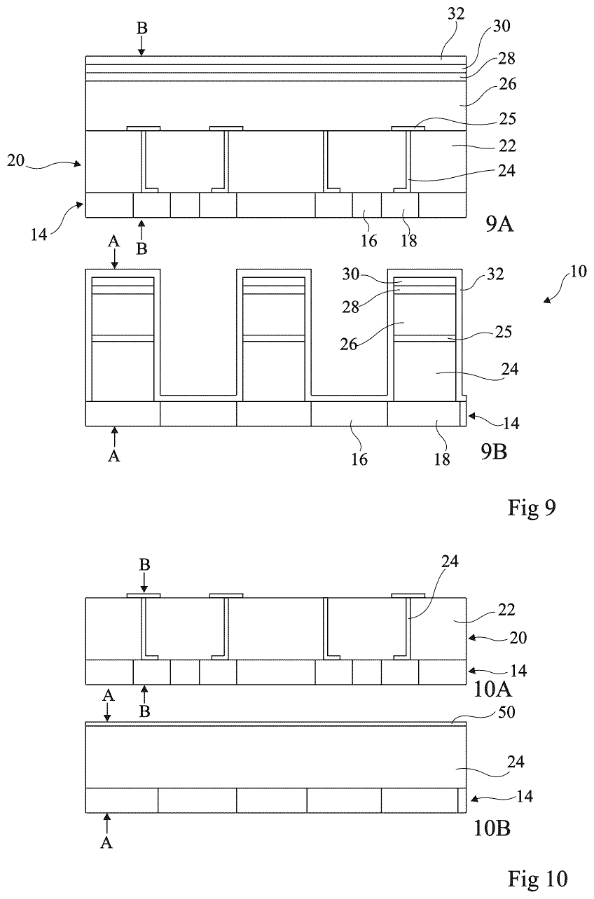

FIG. 9 shows a device resulting from a step of a method of manufacturing the device of FIG. 1. More specifically, FIG. 9 shows two cross-section views 9A and 9B. View 9A corresponds to a cross-section view along plane A-A of view 9B, and view 9B corresponds to a cross-section view along plane B-B of view 9A. Planes A-A and B-B are preferably substantially perpendicular.

During this step, passivation layer 32 is formed. In other words, layer 32 is formed conformally on the structure resulting from the step of FIG. 7. Layer 32 thus preferably covers the upper surfaces of layers 30, portions of the upper surfaces of level 14, and the side walls of the rows, that is, the side walls of layers 22, 25, 26, 28, 30 and of elements 24.

The method may, for example, include additional steps subsequent to the step of FIG. 9. During these steps, the spaces separating the rows may be filled with one or a plurality of insulating layers, not shown.

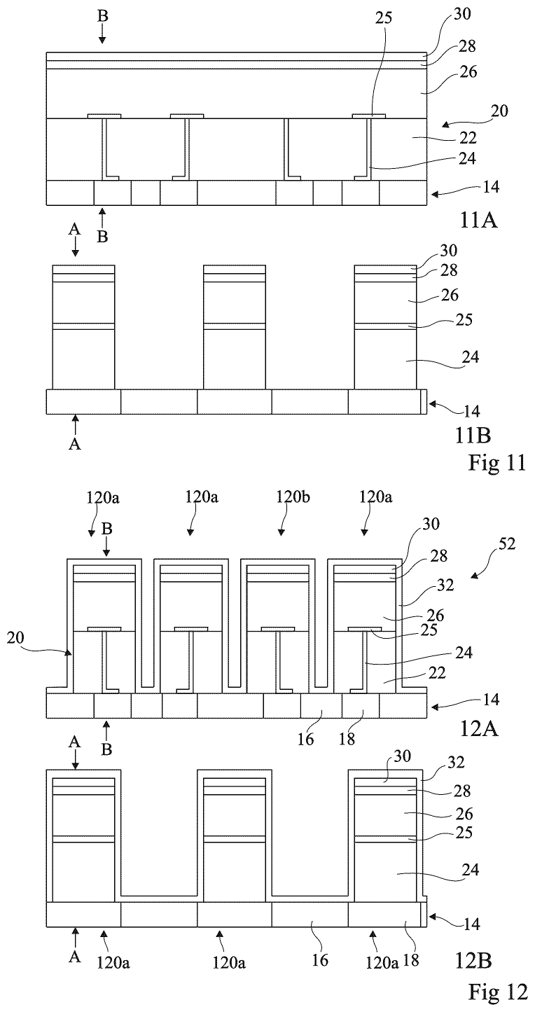

FIGS. 10 and 11 illustrate another method of manufacturing the device of FIG. 1.

FIG. 10 shows a device resulting from a step of another method of manufacturing another device of FIG. 1. More specifically, FIG. 10 shows two cross-section views 10A and 10B. View 10A corresponds to a cross-section view along plane A-A of view 10B, and view 10B corresponds to a cross-section view along plane B-B of view 10A. Planes A-A and B-B are preferably substantially perpendicular.

The step of FIG. 10 is configured to replace the step of FIG. 5. In other words, the method of FIGS. 10 and 11 includes, before the step of FIG. 10, the steps of FIGS. 3 and 4, such as previously described.

The step of FIG. 10 differs from that of FIG. 5 in that layer 42 is etched to form strips 50. The strips extend in the Y direction, that is, the direction in which the columns of memory cells extend. Each strip 50 includes the portions of layer 42 corresponding to the layers 25 of a same column of memory cells. Each strip 50 further includes the portions of layer 42 located between the layers 25 of the column. The dimension of each strip 50 in the X direction is preferably substantially equal to the dimension of layers 25 in the X direction.

In the embodiment of FIGS. 10 and 11, the memory preferably includes columns of cells 12a, that is, columns of the memory array only including cells 12a, and columns of cells 12b, that is, columns of the memory array only including cells 12b. Thus, strips 50 are formed at the locations of cells 12a and are not formed at the locations of cells 12b.

FIG. 11 shows a device resulting from a step of another method of manufacturing the device of FIG. 1. More precisely, FIG. 11 shows two cross-section views 11A and 11B. View 11A corresponds to a cross-section view along plane A-A of view 11B, and view 11B corresponds to a cross-section view along a plane B-B of view 11A. Planes A-A and B-B are preferably substantially perpendicular.

The step of FIG. 11 includes the step of FIG. 6 such as described in relation with FIG. 6.

The step of FIG. 11 further includes a step replacing the step of FIG. 7. More specifically, the step of FIG. 11 includes the steps of FIG. 7 and further includes, during the etching of the rows of memory cells, the etching of strips 50.

The method of FIGS. 10 and 11 further includes steps, not shown. In particular, the method of FIGS. 10 and 11 includes the step of FIG. 9.

Although the method of FIGS. 10 and 11 does not enable to prevent the unintentional etching of layer 26 during the etching of strips 50, the method of FIGS. 10 and 11 enables to form cells 12a in a “wall”-type memory array.

FIG. 12 shows another embodiment of an electronic device 52. More specifically, FIG. 12 shows two cross-section views 12A and 12B. View 12A corresponds to a cross-section view along plane A-A of view 12B, and view 12B corresponds to a cross-section view along plane B-B of view 12A. Planes A-A and B-B are preferably substantially perpendicular.

Device 52 includes the elements of device 10, arranged in identical manner. These elements will not be detailed again. Thus, device 52 includes:
level 14, including layer 16 and contacts 18;
level 20, including layers 22 and elements 24;
layers 25 made of a conductive material;
layers 26 made of a phase-change material;
layers 28 made of a conductive material;
layers 30 made of an insulating material; and
passivation layer 32 made of an insulating material.

Device 52 includes cells 120a, similar to the cells 12a described in relation with FIG. 1, that is, cells configured to contain one value from among at least three values. Device 52 for example includes cells 120b similar to the cells 12b described in relation with FIG. 1, that is, cells configured to contain one value from among at least two values.

Device 52 differs from the device 10 of FIG. 1 in that the memory cells are singulated. In other words, the rows of memory cells are separated into portions corresponding to each memory cell. More specifically, each memory cell 120a includes a portion of layer 22, an element 24, a layer 25, a portion of layer 26, a portion of layer 28, and a portion of layer 30. Each memory cell 12b includes a portion of layer 22, an element 24, a portion of layer 26, a portion of layer 28, and a portion of layer 30.

The memory cells, and more precisely the stacks of each memory cell including level 20, layers 26, 28, 30, and optionally layer 25, are separated from one another. Thus, the different levels and layers of said stacks are not in contact with the stacks of the other cells.

The layer 32 of FIG. 12 differs from the layer 32 of FIG. 1 in that, in FIG. 12, layer 32 covers all the side walls of each cell. Thus, layer 32 separates the cells from one another. In other words, the side walls, for example the four side walls, of layers 22, 26, 28, 30, the upper surface of layer 30, and possibly the side walls of layer 25 and of element 24, are covered by layer 32.

A method of manufacturing device 52 includes the steps of the method of FIGS. 3 to 9 or the steps of the method of FIGS. 10 and 11. The method of manufacturing device 52 includes, for example after the step of FIG. 9 or after the step of FIG. 11, a step of forming of an insulating layer, not shown, covering the structure resulting from FIG. 9 so as to fill the spaces between rows and so as to obtain a planar upper surface. The method then includes the forming of an etch mask including strips, not shown, extending in the Y direction so as to cover the locations of the memory cells. More specifically, each strip, not shown, covers the locations of the memory cells of a column. Each strip further covers the regions separating the cells of said column. The method then includes the etching of the stack, layer 32, and the insulating layer, not shown. The method then for example includes the forming of a layer, not shown, conformally on the structure, the layer, not shown, being for example made of the material of layer 32.

Another manufacturing method includes the steps of the method of FIGS. 3 to 9 or the steps of the method of FIGS. 10 and 11. The method of manufacturing device 52 differs from the method of FIGS. 3 to 9 or from the method of FIGS. 10 and 11 in that, at step 7, or at step 11, the etch masks, formed before the etching of the stack of level 20 and of layers 25, 26, 28, 30, are not strip-shaped but have a shape such that each mask substantially, preferably only, covers the location of a memory cell. Thus, the etching enables to obtain singulated cells.

An advantage of the embodiments is that they enable to obtain layers 26 of phase-change material having straight and planar profiles. In particular, the side walls of layers 26 are not etched during the etching of layer 25.

Another advantage of the embodiments is that they enable to improve the alignment of layer 26 and of layers 25.

Another advantage of the embodiments is that they enable to form wall-type or dot-type memory cells.

Another advantage of the embodiments is that they enable to decrease the memory cell dimensions, which enables to decrease the current necessary for the programming.

Another advantage of the embodiments is that they enable to form, on a same circuit, and possibly in a same memory, cells including a layer 25 and cells which do not include a layer 25.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

A method of manufacturing a memory including at least one first phase-change memory cell (12a, 120a), each first cell (12a, 120a) including a resistive element (24), a first metal layer (25), and a second layer (26) made of a phase-change material, the first layer (25) being located between the resistive element (24) and the second layer (26) including: a. the forming of a level (20) including the resistive element (24); b. the forming of a third metal layer (42) on the level (20); c. the etching of the third layer (42); and then d. the forming of the second layer (26).

The first metal layer (25) is made of TiSiN, of TiN, or of TaN, the third metal layer (42) being made of the same material as the first layer (25).

The device includes at least two first cells (12a, 120a), the first metal layers (25) of different first cells being separated from one another.

The first metal layer (25) is in contact with the resistive element (24) and with the second layer (26) made of a phase-change material.

The device includes at least one second phase-change memory cell (12b, 120b) including a resistive element (24) and a second layer (26) made of a phase-change material, the second layer (26) is in contact with the resistive element (24), the method including the etching of the first layer at the locations of the second cells (12b, 120b).

The device includes rows of memory cells (12a, 12b, 120a, 120b), the cells of the same row include a second layer (26) made of a common phase-change material.

The memory cells (12a, 12b, 120a, 120b) each include a portion of the second layer (26) made of a phase-change material, the portions of the second layer (26) made of a phase-change material of the different cells being separated from one another.

The method includes a step e., subsequent to step d. in which the portions of the first level (20) and of the second layer (26) made of a phase-change material located around the memory cells are etched.

The device includes at least two rows of memory cells (12a, 12b, 120a, 120b), the method including a step e., subsequent to step d., in which the portions of the first level (20) and of the second layer (26) made of a phase-change material located between the two rows of memory cells are etched.

The device includes at least two columns of memory cells, the method including a step f. subsequent to step e., in which the portions of the first level (20) and of the second layer (26) made of a phase-change material located between the two columns of memory cells are etched.

Step c. includes the etching of the third metal layer (42) so as to form the first metal layer (25).

Step c. includes the etching of the third metal layer (42) so as to form strips (50), each including the first layers (25) of first cells (12a) of a same column of memory cells.

Step e. includes the etching of the strips (50) so as to form the first metal layers (25).

The level (20) includes a fourth insulating layer (22) in which the resistive element (24) is arranged, the first layer (25) being in contact with the resistive element (24) and the fourth layer (22), the second layer being formed on and in contact with the first layer (25) and the level (20).

These and other changes can be made to the embodiments in light of the above-detailed description In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming a first level including a resistive element of a first phase-change memory cell;
forming a metal layer on the first level;
forming, from the metal layer, a conductive element of the first phase-change memory cell on the resistive element by etching the metal layer; and
forming a layer of phase-change material on the first level and covering a sidewall and a top surface of the conductive element.

2. The method according to claim 1, wherein the metal layer is made of TiSiN, of TiN, or of TaN.

3. The method according to claim 1, comprising forming at least two first phase-change memory cells each including a respective conductive element separated from each another.

4. The method according to claim 1, wherein the conductive element is in contact with the resistive element and with the layer of phase-change material.

5. The method according to claim 1, comprising:
forming in the level a resistive element of a second phase-change memory cell, the resistive element of the first phase-change memory cell being separated from the resistive element of the second phase-change memory cell;
etching the metal layer to expose the resistive element of the second phase-change memory cell; and
forming the layer of phase-change material in contact with a top surface of the resistive element of the second phase-change memory cell.

6. The method according to claim 5, comprising forming a row of memory cells including the first phase-change memory cell and the second phase-change memory cell wherein the layer of phase-change material is continuous between the first phase-change memory cell and the second phase-change memory cell of the row of memory cells.

7. The method according to claim 1, comprising forming a row of memory cells including a first plurality of first phase-change memory cells, wherein the first phase-change memory cells each include a portion of the layer of phase-change material, the portions of the layer made of phase-change material of the different first phase-change memory cells being separated from one another.

8. The method according to claim 1, comprising, subsequent to forming the layer of phase-change material, etching portions of the first level and of the layer of phase-change material located around the first phase-change memory cell.

9. The method according to claim 1, comprising:
forming at least two rows of memory cells each row including at least one first memory cell; and
etching the portions of the first level and of the layer of phase-change material between the two rows of memory cells.

10. The method according to claim 9, comprising:
forming at least two columns of memory cells each including at least one first phase-change memory cell; and
etching the portions of the first level and of the layer of phase-change material located between the two columns.

11. The method according to claim 1, wherein etching the metal layer forms strips, each including a plurality of conductive elements of respective first phase-change memory cells of a same column of memory cells.

12. The method according to claim 11, comprising etching the strips to form the conductive elements.

13. The method according to claim 1, wherein the first level includes an insulating layer in which the resistive element is arranged, the conductive element being in contact with the resistive element and the insulating layer, the layer of phase-change material being formed on and in contact with the conductive element and the insulating layer.

14. A method, comprising:
forming a plurality of resistive elements in a first insulating layer and each having a top surface substantially coplanar with a top surface of the first insulating layer;
forming a plurality of conductive elements each in contact with the top surface of a respective resistive element and the top surface of the insulating layer; and
forming a layer of phase change material on the top surface of the insulating layer, on a sidewall of each conductive element, and on the top surface of each conductive element, wherein each of a plurality of first phase-change memory cells includes a respective resistive element, a respective conductive element, and a respective portion of the layer of phase-change material.

15. The method of claim 14, wherein forming the plurality of conductive elements includes:
forming a layer of conductive material on the insulating layer and on the top surfaces of the resistive elements; and
forming the conductive elements from the layer of conductive material by patterning the layer of conductive material.

16. The method of claim 15, wherein patterning the layer of conductive material includes exposing a top surface of one of the resistive elements, the method comprising forming the layer of phase change material in direct contact with the top surface of the exposed resistive element, the exposed resistive element being part of a second phase-change memory cell.

17. The method of claim 16, wherein the first phase-change memory cells are multi-bit memory cells, wherein the second phase-change memory cell is a single bit memory cell.

18. A device, comprising a layer of insulating material and a phase-change memory cell, the phase-change memory cell including:
a metal contact;
a resistive element in the layer of insulating material and on a top surface of the metal contact;
a conductive element in contact with a top surface of the resistive element and the layer of insulating material;
a layer of phase-change material on a top surface of the layer of insulating material, on a side surface of the conductive element, and on a top surface of the conductive element.

19. The device of claim 18, comprising a metal layer on a top surface of the layer of phase change material.

20. The device of claim 19, comprising a second layer of insulating material on a side surface of the metal layer, on a side surface of the layer of phase-change material, on a side surface of conductive element, and on a side surface of the first layer of insulating material.
